(19) United States
(12) Patent Application Publication
(10) Pub. No.: US 2010/0033917 A1
(43) Pub. Date: Feb. 11, 2010

(54) COMPUTER

(75) Inventors: Lian-Chang Du, Shanghai City (CN); Shou-Jen Yang, Taipei City (TW)

Correspondence Address: J C PATENTS, 4 VENTURE, SUITE 250, IRVINE, CA, 92618, US

(73) Assignee: INVENTEC CORPORATION, Taipei City (TW)

(21) Appl. No.: 12/326,289

(22) Filed: Dec. 2, 2008

(30) Foreign Application Priority Data
Aug. 8, 2008 (CN) 200810145472.0

(51) Int. Cl. H05K 7/14

(52) U.S. Cl. 361/679.32

(57) ABSTRACT

A computer including a chassis, a mainboard, a plurality of computing units, a plurality of I/O interface ports, a plurality of first storage apparatuses, a rack, at least one expansion storage apparatus, and a fan module is provided. The chassis includes a front end and a rear end opposite to the front end. The mainboard and the computing units are disposed in the chassis. The computing units are coupled to the mainboard. The I/O interface ports are disposed at the rear end and coupled to the mainboard. The first storage apparatuses are arranged in an array form at the front end of the chassis. The rack is disposed in an assembling opening at the rear end. The expansion storage apparatus is disposed in the rack and is coupled to the mainboard. The fan module is disposed on the rack for providing heat dissipation to the fan module.

### CROSS-REFERENCE TO RELATED APPLICATION

This application claims the priority benefit of P.R.C. patent application serial no. 200810145472.0, filed on Aug. 8, 2008. The entirety of the above-mentioned patent application is hereby incorporated by reference herein and made a part of specification.

### BACKGROUND OF THE INVENTION

1. Field of the Invention

The present invention generally relates to a computer, and more particularly, to a computer having an expansion storage apparatus.

2. Description of Related Art

Because of the development of information communication technologies and the popularization of information media, computers including servers, workstations, desktop computers, notebook computers, or even industrial computers have now become necessary for people's daily life and routine jobs. As an example, servers, such as exchangers, routers, and hardware firewalls, mostly adopt rack structures. Such a rack structure is usually configured with a flat shape. A slidable bracket is detachably provided at a certain height in the chassis as desired, for lodging network equipment such as a server, a hub, or a redundant array of independent disks (RAID) pack.

Generally, a computer, e.g., a server, is usually configured with a fixed internal volume for accommodating required components. As such, accommodation spaces of the computer are adapted for devices having particular specifications, such as a hard disk drive (HDD), and a CD/DVD drive only, and usually cannot be compatibly used by other hardware. Further, when intending to employ an additional storage apparatus into the computer, a user has to further consider the present space layout inside the computer. Therefore, the expandability of the computer is thus restricted accordingly.

Furthermore, storage apparatuses, e.g., HDDs, usually produce a lot of heat in operation, while the heat dissipation apparatus inside the computer is usually designed corresponding to the original space layout. As such, when the user employs a storage apparatus such as an HDD in the computer in addition, the original heat dissipation apparatus often fails to provide effective heat dissipation effect to the expanded storage apparatus. Therefore, the performance and reliability of the computer, in its entirety, may be affected.

### SUMMARY OF THE INVENTION

Accordingly, the present invention is directed to provide a computer adapted for being expanded with an expansion storage apparatus and providing effective heat dissipation to the expanded storage apparatus. The computer is thus featured with an optimal expandability and operation performance.

The present invention is further directed to provide a computer including an expansion storage apparatus, a fan module, and a shock absorption buffer between the expansion storage apparatus and the fan module. The computer is thus featured with a good reliability.

The present invention provides a computer, including a chassis, a mainboard, a plurality of computing units, a plurality of input/output (I/O) interface ports, a plurality of first storage apparatuses, a rack, at least one expansion storage apparatus, and a fan module. The chassis includes a front end and a rear end opposite to the front end. The mainboard and the computing units are disposed in the chassis. The computing units are coupled to the mainboard. The I/O interface ports are disposed at the rear end of the chassis, and are coupled to the mainboard. The first storage apparatuses are arranged in an array form at the front end of the chassis. The rack is disposed in an assembling opening at the rear end of the chassis. The expansion storage apparatus is disposed in the rack and is coupled to the mainboard. The fan module is disposed on the rack for providing heat dissipation to the expansion storage apparatus.

According to an embodiment of the present invention, the expansion storage apparatus for example is a hard disk drive (HDD).

According to an embodiment of the present invention, the assembling opening at the rear end of the chassis has a size greater than or equal to a minimum size which is adapted for accommodating the rack therein, so that the assembling opening is compatible for alternative racks having different sizes. Further, the chassis may further include an adjusting baffle, disposed in the front of the assembling opening, for sheltering a rest portion of the assembling opening which is unoccupied by the rack.

According to an embodiment of the present invention, the computer further includes a buffer member, disposed at a joint of the fan module and the rack for providing a buffer therebetween. Further, the fan module for example includes a fan frame, a locking member, and a fan body. The locking member fixes the fan frame on the rack, and the fan body is disposed inside the fan frame.

Specifically, the fan frame may further include a joint portion. The joint portion includes at least one locking hole. The locking member is a screw having a thread rod and a head. The fan frame can be fixed to the rack by inserting the thread rod through the locking hole. Further, the buffer member for example is an elastic bumper block having a first neck portion, two supporting portions configured at two lateral sides of the first neck portion, and a through hole configured through the supporting portions and the first neck portion. The first neck portion is positioned inside the locking hole. The screw is inserted through the elastic bumper block via the through hole. The two supporting portions are positioned between the joint portion and the rack, and between the joint portion and the head of the screw, respectively. Further, the locking hole for example is a recess positioned at an edge of the joint portion. The recess has a size which is sufficient for allowing the first neck portion entering the recess from the edge of the joint portion, and being engaged inside the recess.

Further, the computer may further includes a circuit board, and at lest one standoff. The circuit board is disposed between the fan module and the rack. The standoff is positioned corresponding to the locking hole, and is protruded out from one side of the rack toward the fan module. The screw is locked inside the standoff, for fixing relative positions of the fan module, the circuit board, and the rack. One of the supporting portions of the elastic bumper block is supportively provided between the standoff and the joint portion of the fan frame.

According to an embodiment of the present invention, the foregoing standoff for example includes a second neck portion, while the circuit board includes at least one engaging slot. The engaging slot has an entrance end and an engaging end. The entrance end is configured with a size sufficiently allowing the standoff entering the engaging slot, while the engaging end is configured with a size allowing the necking portion of the standoff entering therein only, so that the circuit board can be fixed on the second neck portion of the standoff via the engaging end.

According to an embodiment of the present invention, the computer further includes a tray, assembled in the rack for loading the expansion storage apparatus. Being loaded on the tray, the expansion storage apparatus is adapted for being plugged into and out from the rack.

As discussed above and according to the present invention, the computer includes an expansion storage apparatus, and a fan module disposed beside the expansion storage apparatus, thus providing heat dissipation to the expansion storage apparatus, thus improving the operation performance of the computer. Further, for minimizing the negative affection caused by vibration generated by the fan module, a buffer member is disposed between the fan module and the expansion storage apparatus, for absorbing the shock of the vibration generated by the fan module during operation. Upon the buffer provided by the buffer member, the computer can achieve an improved reliability.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B illustrate a front view and a back view of a server according to an embodiment of the present invention.

FIG. 2 is a front view of a rack with an expansion storage apparatus assembled thereto according to an embodiment of the present invention.

FIG. 3 is a back view of the rack with the expansion storage apparatus assembled thereto according to an embodiment of the present invention.

FIG. 4 is a partial explosive view of the structure shown in FIG. 3.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention can be applied in different computers, e.g., servers, workstations, or desktop computers, and thus there is no set limits on the application of the present invention. Moreover, those skilled in the art should be taught by the disclosure for further adjusting or modifying the disclosed internal configuration of the computer within the scope of the present invention according to the spirit thereof. As embodied and broadly described herein, a server is taken as an example for exemplifying the details of the present invention.

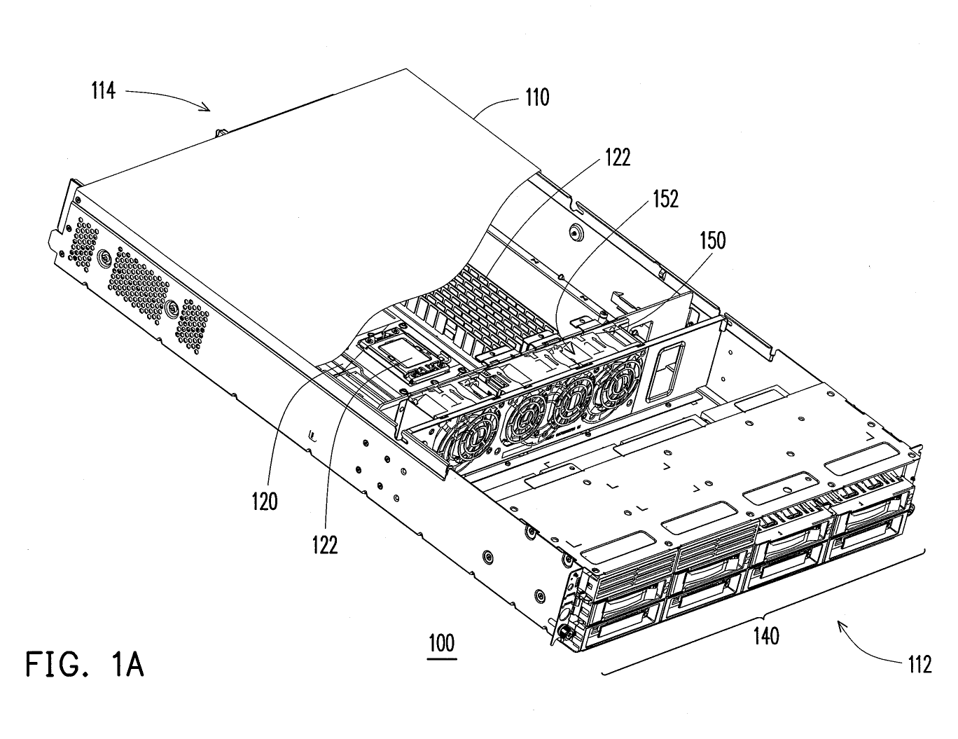

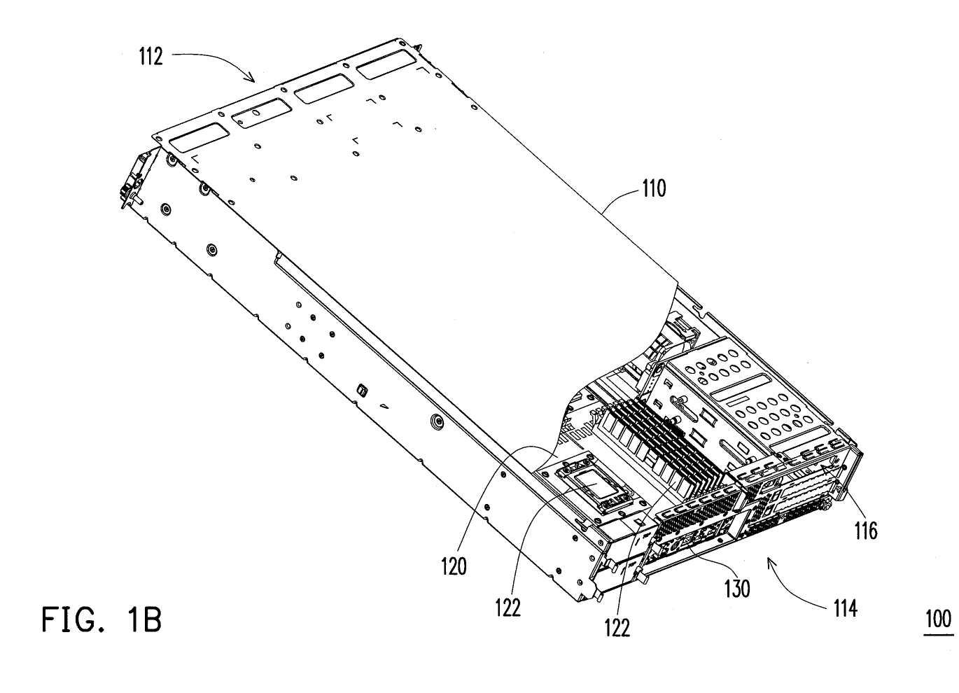

FIGS. 1A and 1B illustrate a front view and a back view of a server according to an embodiment of the present invention. Referring to FIGS. 1A and 1B, a server 100 is shown in the drawings. The server 100 includes a chassis 110. The chassis 110 is partitioned into a plurality of areas for installing different apparatuses. For example, a mainboard 120 is installed at a bottom of the chassis 110. The server 100 further includes a plurality of computing units 122, (e.g., a central processing unit (CPU), a memory, or other chipsets) are provided on or coupled to the mainboard 110. The server 100 further includes a plurality of input/output (I/O) interface ports 130 coupled to the mainboard 120. The input/output (I/O) interface ports 130 for example are COM, PS2, USB, or IEEE-1394 interface ports. Further, a storage apparatus array 140, e.g., a hard drive disk (HDD) array is disposed at a front end of the chassis 110, and is coupled to the mainboard 120. A system fan module 150 integrating a plurality of fan units 152 for example is disposed in a central area of the chassis 110 for cooling components inside the chassis 110.

Referring to FIG. 1B, for adding an expansion storage apparatus, an assembling opening 116 is further configured at a rear end of the chassis 110. The assembling opening 116 corresponds to an internal space of the chassis 110. The internal space can be used for accommodating an interface car, a storage apparatus, or other electronic apparatuses. In the current embodiment, the present invention is exemplified with a rack 160 accommodated in the assembling opening 116. The rack 160 is adapted for loading an expansion storage apparatus 170. The expansion storage apparatus 170 for example is an HDD or a CD/DVD driver. In the current embodiment, the expansion storage apparatus 170 is illustrated for example by two HDDs. However, the quantity or type of the expansion storage apparatus 170 is not restricted by the present invention, and can be adaptively determined by those skilled in the art in accordance with the practical application.

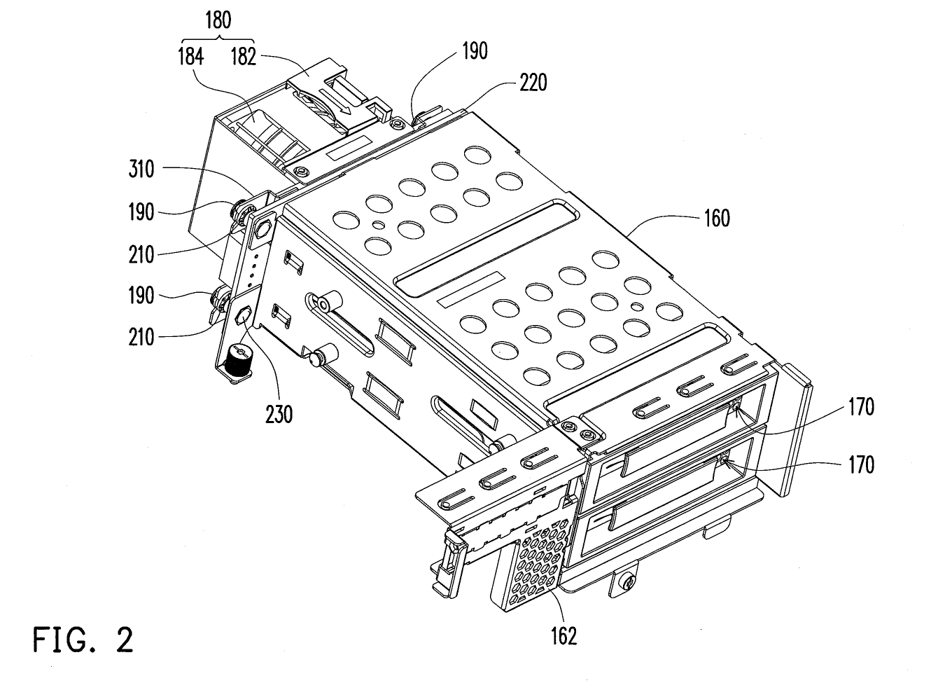

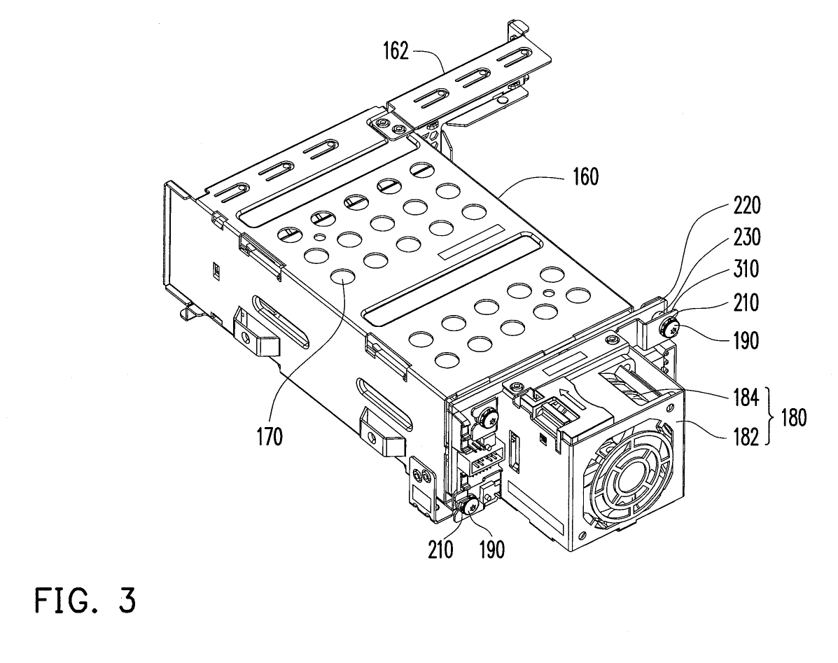

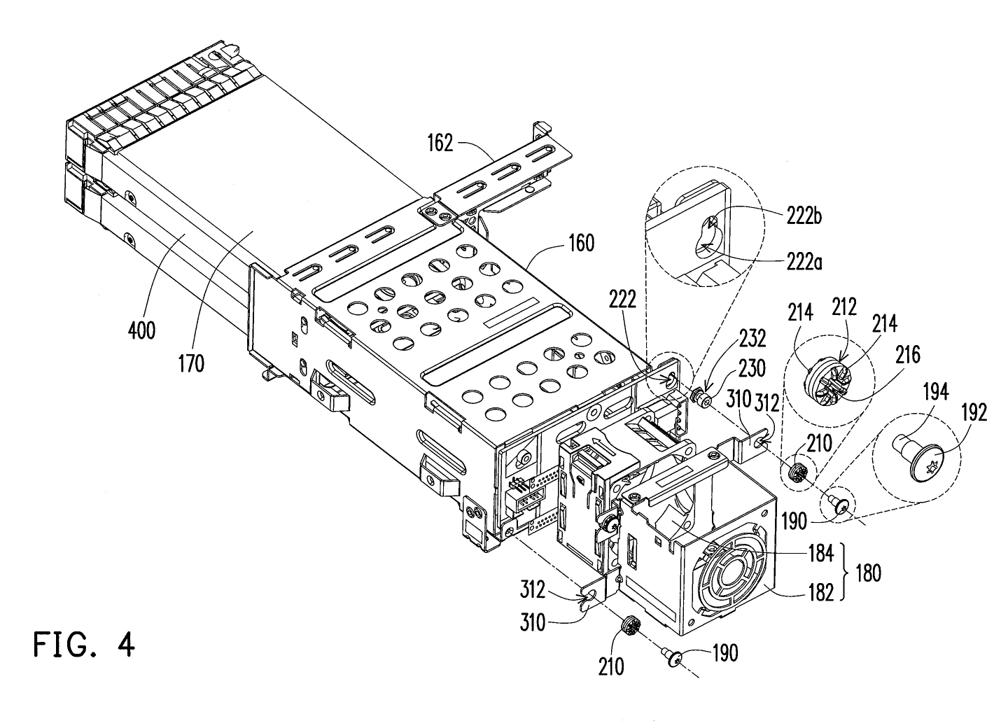

FIG. 2 is a front view of the rack 160 with the expansion storage apparatus 170 assembled thereto according to an embodiment of the present invention. FIG. 3 is a back view of the rack 160 with the expansion storage apparatus 170 assembled thereto according to an embodiment of the present invention. FIG. 4 is a partial explosive view of the structure shown in FIG. 3. Referring to FIGS. 2 through 4, more details and features of the present invention are shown.

As shown in FIG. 2, for allowing the assembling opening 116 compatible with expansion storage apparatuses 170 of different sizes and the corresponding racks 160, the assembling opening 116 is preferred to be configured with a size which is grater than or equal to a minimum size adapted for accommodating the rack 160. After the rack 160 is assembled to the assembling opening 116, the assembling opening 116 may be not completely occupied by the rack 160. A portion of the assembling opening 116 unoccupied by the rack 160 configures a vacancy at a rear end 114 of the chassis 110. As such, it is preferred to further provide an adjusting baffle 162 in the front of the assembling opening 116 at the rear end 114, i.e., the vacancy, for sheltering the unoccupied portion of the assembling opening 116, so as to prevent alien objects from entering into the chassis 110. Further, as shown in FIG. 4, the expansion storage apparatus 170 is further provided with a tray 400 at an outside the expansion storage apparatus 170 for loading the expansion storage apparatus 170. Being loaded on the tray 400, the expansion storage apparatus 170 is adapted for being plugged into and out from the rack 160.

As shown in FIGS. 2 through 4, the current embodiment further provides a fan module 180 at a backside of the rack 160, for providing heat dissipation to the expansion storage apparatus 170. The fan module 180 is fixed on the rack 160. Considering vibration generated by the fan module 180 in operation, the current embodiment further provides a buffer member 210 at a joint between the fan module 180 and the rack 160, for absorbing a shock caused by the vibration and providing a buffer therebetween.

Specifically, as shown in FIGS. 3 and 4, the fan module 180 of the current embodiment includes a fan frame 182, a fan body 184, and a locking member 190. The fan body 184 is disposed in the fan frame 182. The fan frame 182 includes a joint portion 310 having a locking hole 312. Further, a circuit board 220 is disposed between the fan module 180 and the rack 160. The fan module 180 is coupled to the circuit 220. The rack 160 is further provided with a standoff 230 corresponding to locking hole 312. The standoff 230 is configured protruding out from one side of the rack 160 toward the fan module 180.

Referring to FIGS. 3 and 4 again, the buffer member 210 of the embodiment for example is an elastic bumper block having a first neck portion 212, two supporting portions 214 configured at two lateral sides of the first neck portion 212, and a through hole 216 configured through the supporting portions 214 and the first neck portion 212. Further, the locking hole 312 for example is a recess 312 positioned at an edge of the joint portion 310. The recess 312 has a size which is sufficient for allowing the first neck portion 212 entering the recess 312 from the edge of the joint portion 310, and being engaged inside the recess 312. The two supporting portions 214 positioned at the two lateral sides of the first neck portion 212 are supportively positioned at two opposite sides of the joint portion 310.

Further, the locking member 190 of the current embodiment 190 for example is a screw having a head 192 and a thread rod 194. The head 192 is inserted through the elastic bumper block 210 from the through hole 216 of the elastic bumper block 210, and is locked in the standoff 230 thereby, thus fixing relative positions of the fan module 180, the circuit board 220, and the rack 160. The two supporting portions 214 are positioned between the joint portion 310 and the rack 160, and between the joint portion 310 and the head 192 of the screw 190, respectively.

Moreover, according to an aspect of the embodiment, for fixing the circuit board 220 onto the rack 160, the configuration of the standoff 230 can be modified. As shown in FIG. 4, the standoff 230 includes a second neck portion 232, while the circuit board 220 includes at least one engaging slot 222. The engaging slot 222 has an entrance end 222a and an engaging end 222b. The entrance end 222a is configured with a size sufficiently allowing the standoff 230 entering the engaging slot 222, while the engaging end 222b is configured with a size allowing the necking portion 232 of the standoff 230 entering therein only, so that the circuit board 220 can be fixed on the second neck portion 232 of the standoff 230 via the engaging end 222b.

In summary, the present invention provides an expansion storage apparatus in addition to an original HDD array of a computer, and further provides a fan module on a rack of the expansion storage apparatus for providing heat dissipation to the expansion storage apparatus. Further, the present invention provides a buffer at a joint between the fan module and the rack, for absorbing a shock caused by vibration generated by the fan module in operation. As such, the present invention not only provides effective heat dissipation to the expansion storage apparatus, but also helps to improve the operation performance and reliability of the computer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A computer, comprising:
a chassis, having a front end and a rear end positioned opposite to the front end;
a mainboard, disposed in the chassis;
a plurality of computing units, disposed in the chassis and coupled to the mainboard;
a plurality of input/output (I/O) interface ports, disposed at the rear end of the chassis, and coupled to the mainboard;
a plurality of first storage apparatuses, arranged in an array form at the front end of the chassis;
a rack, disposed in an assembling opening at the rear end of the chassis;
at least one expansion storage apparatus, disposed in the rack and coupled to the mainboard; and
a fan module, disposed on the rack.

2. The computer according to claim 1, wherein the expansion storage apparatus comprises a hard disk drive (HDD).

3. The computer according to claim 1, wherein the assembling opening has a size greater than or equal to a minimum size which is adapted for accommodating the rack therein, so that the assembling opening is compatible for alternative racks having different sizes.

4. The computer according to claim 3, wherein the chassis further comprises an adjusting baffle, disposed in the front of the assembling opening, for sheltering a portion of the assembling opening which is unoccupied by the rack.

5. The computer according to claim 1, wherein the computer further comprises a buffer member, disposed at a joint of the fan module and the rack.

6. The computer according to claim 5, wherein the fan module comprises:
a fan frame;
a locking member, locking the fan frame onto the rack; and
a fan body, disposed inside the fan frame.

7. The computer according to claim 6, wherein the fan frame further comprises a joint portion having at least one locking hole, and the locking member is a screw having a head and a threaded rod, wherein the fan frame is fixed onto the rack by inserting the threaded rod through the locking hole.

8. The computer according to claim 7, wherein the buffer member is an elastic bumper block having a first neck portion, two supporting portions configured at two lateral sides of the first neck portion, and a through hole configured through the supporting portions and the first neck portion, the first neck portion being positioned inside the locking hole, the screw being inserted through the elastic bumper block via the through hole, and the two supporting portions being positioned between the joint portion and the rack, and between the joint portion and the head of the screw, respectively.

9. The computer according to claim 8, wherein the locking hole is a recess positioned at an edge of the joint portion, the recess having a size which is sufficient for allowing the first neck portion entering the recess from the edge of the joint portion, and being engaged with the recess.

10. The computer according to claim 8, further comprising:
a circuit board, disposed between the fan module and the rack; and
at lest one standoff, positioned corresponding to the locking hole, and being protruded out from one side of the rack toward the fan module, wherein the screw is locked inside the standoff, for fixing relative positions of the fan module, the circuit board, and the rack, and one of the supporting portions of the elastic bumper block is supportively provided between the standoff and the joint portion of the fan frame.

11. The computer according to claim 10, wherein the standoff comprises a second neck portion, and the circuit board comprises at least one engaging slot, the engaging slot having an entrance end and an engaging end, the entrance end being configured with a size sufficiently allowing the standoff entering the engaging slot, the engaging end being configured with a size allowing the necking portion of the standoff entering therein only, and the circuit board being fixed on the second neck portion of the standoff via the engaging end.

12. The computer according to claim 1, further comprising a tray assembled in the rack for loading the expansion storage apparatus, wherein when being loaded on the tray, the expansion storage apparatus is pluggable into and out from the rack.
